(19) United States
(12) Patent Application Publication
(10) Pub. No.: US 2008/0217654 A1
(43) Pub. Date: Sep. 11, 2008

(54) Semiconductor device and method of fabricating the same

(76) Inventors: Yuuji Kitamura, Mizuho-shi (JP); Yoshikazu Ibara, Motosu-gun (JP)

Correspondence Address: MCDERMOTT WILL & EMERY LLP, 600 13TH STREET, N.W., WASHINGTON, DC, 20005-3096, US

(21) Appl. No.: 12/073,045

(22) Filed: Feb. 28, 2008

(30) Foreign Application Priority Data
Feb. 28, 2007 (JP) JP2007-048247

(51) Int. Cl. H01L 29/737; H01L 21/331

(52) U.S. Cl. 257/190; 438/318; 257/E29.193; 257/E21.371

(57) ABSTRACT

A semiconductor device includes an element isolation film having an inclined portion and a flat portion, a protective film formed not on the inclined portion but on the flat portion of the element isolation film, and an outer base layer formed to extend from on a surface of an active region surrounded by the element isolation film to on the protective film.

### CROSS-REFERENCE TO RELATED APPLICATIONS

The priority application number JP2007-048247, Method of Fabricating Semiconductor Device, Feb. 28, 2007, yuzi Kitamura, Yoshikazu Ibara, upon which this patent application is based is hereby incorporated by reference.

### BACKGROUND OF THE INVENTION

1. Field of the Invention

The present invention relates to a semiconductor device and a method of fabricating the same.

2. Description of the Background Art

Recently, as portable electronic apparatuses such as a portable telephone, a personal digital assistance (PDA), a digital video camera (DVC), and a digital steel camera (DSC) have sophisticated, a system LSI attaining high integration and speeding up is demanded. A semiconductor device (heterojunction bipolar transistor) in which a base layer is made of silicon germanium (SiGe) has attracted attention as a module attaining the high speed operational system LSI.

FIG. 13 is an exemplary structure of a conventional heterojunction bipolar transistor. In the conventional heterojunction bipolar transistor, a collector layer 102 is formed on a p-type silicon semiconductor substrate 101. An element isolation film 103 having inclined portions 103a and a flat portion 103b is formed on an upper portion of the collector layer 102 by LOCOS (local oxidation of silicon). A protective film 109 formed by a two-layer structure of a silicon oxide film 104 and a polycrystalline silicon film 105 is so formed on a surface of the element isolation film 103 as to cover the inclined portions 103a and the flat portion 103b. A SiGe layer 106 (106a and 106b) is formed on a region surrounded by the element isolation film 103 (active region A) and the protective film 109. A silicon film 107 (107a and 107b) is formed on the SiGe layer 106a. The SiGe layer 106a and the silicon film 107a constitute a base layer. An emitter layer 113 and an emitter electrode 108a are formed on the silicon film 107a. A side wall 111 is formed on side surfaces of the emitter layer 113 and the emitter electrode 108a. The SiGe layer 106b, the silicon film 107b and a diffusion layer 112a formed on the active region A constitutes an outer base layer.

When the SiGe layer is formed on and in contact with the element isolation film 103, a stacking fault (defects) disadvantageously occur on the SiGe layer formed on the active region A in general. Therefore, the protective film 109 formed by the silicon oxide film 104 and the polycrystalline silicon film 105 is formed up to at a position as close as possible to the active region A, namely the inclined portion 103a of the element isolation film 103 and the SiGe layer 106b is formed on the surface.

Birds' beaks of the inclined portions 103a of the element isolation film 103 adjacent to each other are formed as short as possible for refining a device in general, and a base electrode is formed on the element isolation film 103. In other words, spread in a transverse direction of the inclined portions 103a of the element isolation film 103 formed by LOCOS is suppressed, thereby reducing an area of the element isolation region.

When the silicon oxide film 104 and the polycrystalline silicon film 105 are formed on the inclined portion 103a at the time of refining the device, however, size of unevenness is increased since unevenness due to the inclined portion 103a is added in addition to unevenness due to the thickness of the protective film 109. When the SiGe layer 106b is formed in such a uneven state, coatability of the SiGe layer 106b to the uneven portions is disadvantageously deteriorated. Consequently, a bipolar transistor (semiconductor device) having high reliability can not be disadvantageously stably fabricated due to deterioration of the coatability of the SiGe layer 106b on the uneven portions.

### SUMMARY OF THE INVENTION

A semiconductor device according to a first aspect of the present invention comprises an element isolation film having an inclined portion and a flat portion, a protective film formed not on the inclined portion but on the flat portion of the element isolation film, and an outer base layer formed to extend from on a surface of an active region surrounded by the element isolation film to on the protective film.

A method of fabricating a semiconductor device according to a second aspect of the present invention comprises steps of forming an element isolation film having an inclined portion and a flat portion on a semiconductor substrate, forming a protective film so as to be formed not on the inclined portion but on the flat portion of the element isolation film, and forming an outer base layer so as to extend from on a surface of an active region surrounded by the element isolation film to on the protective film.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view showing a structure of a semiconductor device according to this embodiment;

FIGS. 2 to 11 are sectional views for illustrating a step of fabricating the semiconductor device according to this embodiment;

FIG. 12 is a sectional view for illustrating a semiconductor device according to a modification of this embodiment; and

FIG. 13 is a sectional view showing a structure of a conventional bipolar transistor.

### DESCRIPTION OF THE PREFERRED EMBODIMENTS

An Embodiment of the present invention will be hereinafter described with reference to the drawings.

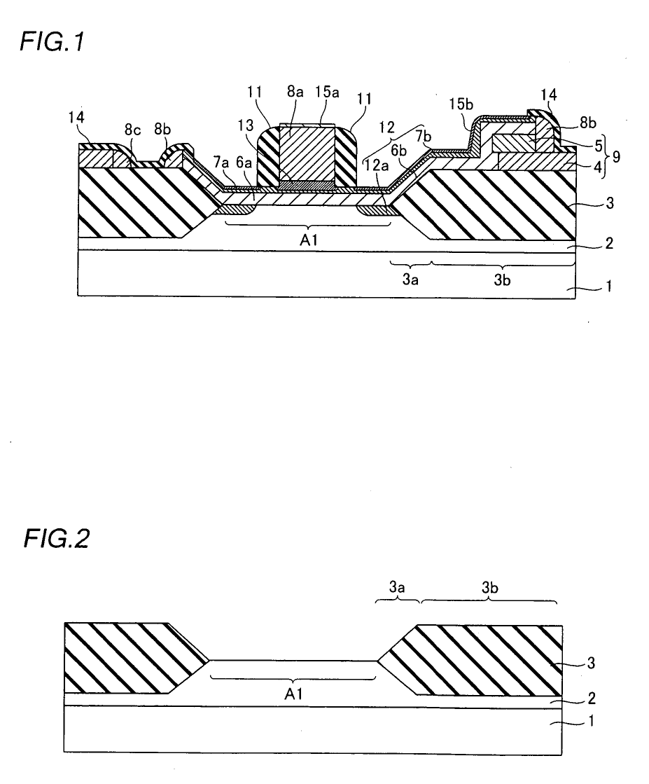

A structure of a semiconductor device according to the embodiment of the present invention will be now described with reference to FIG. 1. According to this embodiment, the present invention is applied to a SiGe base heterojunction bipolar transistor.

In the semiconductor device according to this embodiment, an epitaxial layer made of n-type silicon having a function as a collector layer 2 is formed on a surface of a p-type silicon semiconductor substrate 1. An element isolation film 3 made of a silicon oxide film formed by LOCOS is formed on a part of the collector layer 2. A region surrounded by the element isolation film 3 is an active region A1. The element isolation film 3 has inclined portions 3a and a flat portion 3b. A protective film 9 formed by a two-layer structure of a silicon oxide film 4 and a polycrystalline silicon film 5 is formed on the flat portion 3b of the element isolation film 3. More specifically, a polycrystalline silicon film 5 is formed on a surface of the silicon oxide film 4.

According to this embodiment, the protective film 9 is formed not on the inclined portion 3a of the element isolation film 3 but on the flat portion 3b of the element isolation film 3. An end closer to the active region A1 of the protective film 9 is arranged at a position spaced from the boundary between the inclined portion 3a and the flat portion 3b of the element isolation film 3 toward a side opposite to the active region A1 by a prescribed interval. More specifically, the end of the protective film 9 is arranged at a position spaced from the boundary between the active region A1 and the inclined portion 3a of the element isolation film 3 toward the side opposite to the active region A1 by about 300 nm and spaced from the boundary between the inclined portion 3a and the flat portion 3b of the element isolation film 3 toward the side opposite to the active region A1 by about 150 nm. In other words, the respective ends of the silicon oxide film 4 and the polycrystalline silicon film 5 are so formed as to be located on the flat portion 3b of the element isolation film 3. The end of the polycrystalline silicon film 5 is located on a side closer to the active region A1 than the end of the silicon oxide film 4.

A SiGe layer 6 is formed so as to extend from on the active region A1 of the collector layer 2 to on the protective film 9. More specifically, the SiGe layer 6 is so formed as to cover the inclined portion 3a of the element isolation film 3, a region not covered with the protective film 9 in flat portion 3b of the element isolation film 3, and the protective film 9. A silicon film 7 is formed on a surface of the SiGe layer 6. A portion formed on the active region A1 in the SiGe layer 6 (SiGe layer 6a) and a portion formed on the SiGe layer 6a in the silicon film 7 (silicon film 7a) constitute a base layer.

A diffusion layer 12a is formed on the active region A1, and the diffusion layer 12a, a portion formed on a region other than the active region A1 in the SiGe layer 6 (SiGe layer 6b), a portion formed on the SiGe layer 6b in the silicon film 7 (silicon film 7b) constitute an outer base layer 12. A p-type impurity is implanted into the outer base layer 12.

An emitter layer 13 made of an n-type diffusion layer is formed on the silicon film 7a constituting the base layer. An emitter electrode 8a is formed on the emitter layer 13. A side wall insulating film 11 is formed so as to surround the emitter electrode 8a and the emitter layer 13. A side wall 8b made of polycrystalline silicon is formed so as to be in contact with the ends of the SiGe layer 6b and the silicon film 7b constituting the outer base layer 12. Similarly, a side wall 8c made of polycrystalline silicon is also formed on a portion in contact with one of ends of silicon oxide film 4 constituting the protective film 9. A silicon oxide film 14 is so formed as to cover the side walls 8b and 8c and the silicon oxide film 4.

Silicide films (cobalt silicide) 15a and 15b for making surfaces low resistance layers are formed on surfaces of the emitter electrode 8a and the outer base layer 12 respectively.

According to this embodiment, as hereinabove described, the protective film 9 is formed not on the inclined portion 3a of the element isolation film 3 but on the flat portion 3b of the element isolation film 3. At this time, the end of the protective film 9 is arranged at the position spaced from the boundary between the inclined portion 3a and the flat portion 3b of the element isolation film 3 toward the side opposite to the active region A1 by the prescribed interval. According to this structure, an uneven portion occurring on the end of the protective film 9 and an uneven portion caused by the inclined portion 3a of the element isolation film 3 can be formed at separate positions and hence size of unevenness can be reduced by size of the unevenness caused by the inclined portion 3a of the element isolation film 3 as compared with size of unevenness caused when the unevenness caused by the inclined portion 3a is added to the unevenness occurring on the end of the protective film 9. Therefore, coatability of the SiGe film 6 formed on the uneven portion of the protective film 9 can be inhibited from deterioration and hence the semiconductor device having high reliability can be stably fabricated. The yield of fabrication can be inhibited from being reduced due to deterioration of the coatability of the SiGe film 6.

A process of fabricating the semiconductor device according to the embodiment of the present invention will be now described with reference to FIGS. 1 to 11.

As shown in FIG. 2, the collector layer 2 is formed by stacking the epitaxial layer of n-type silicon on the semiconductor substrate 1 made of p-type silicon. The element isolation film 3 of a LOCOS film is formed on a part of the collector layer 2. The region surrounded by the element isolation film 3 is the active region A1.

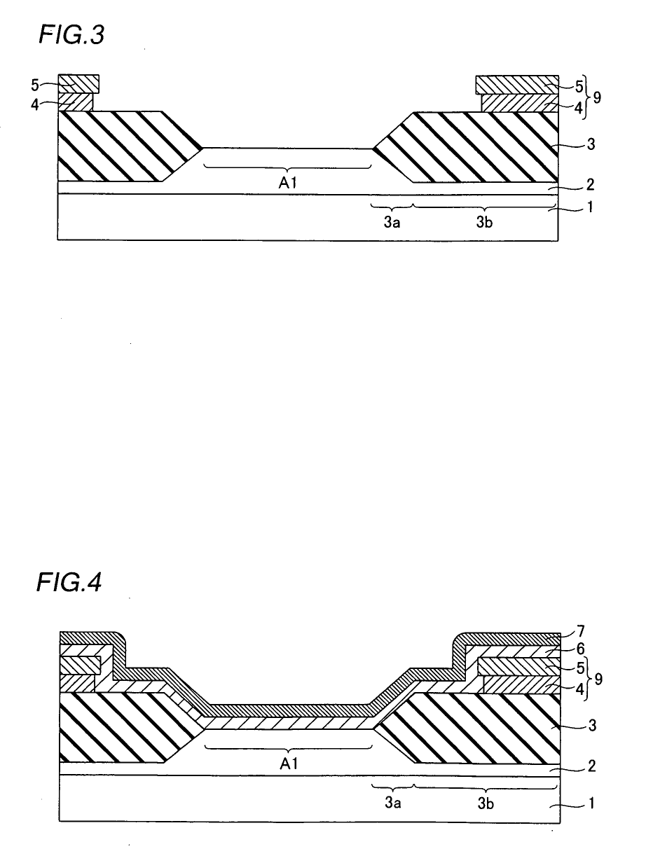

As shown in FIG. 3, the silicon oxide film 4 and the polycrystalline silicon film 5 employed as the protective film 9 are deposited each with a thickness of about 50 nm in this order by low pressure CVD (chemical vapor deposition). A resist film having a prescribed pattern is formed on the polycrystalline silicon film 5 by lithography. The resist film is employed as a mask for patterning the polycrystalline silicon film 5 by dry etching. Continuously, this polycrystalline silicon film 5 is employed as a mask for patterning the silicon oxide film 4 by wet etching with hydrofluoric acid or the like. At this time, the protective film 9 is patterned so as to have the end on the flat portion 3b of the element isolation film 3. At this time, the silicon oxide film 4 is isotropically removed by wet etching, whereby undercut, a shape where the end of the silicon oxide film 4 as a lower layer is concave with respect to the end of the polycrystalline silicon film 5 as an upper layer, occurs on the end of the silicon oxide film 4 as the lower with respect to the polycrystalline silicon film 5.

As shown in FIG. 4, the p-type SiGe layer 6 doped with boron (B) having about 1×10¹⁹ cm⁻³ by low pressure CVD and the silicon film 7 containing no germanium (Ge) are epitaxially grown respectively. The thicknesses of the SiGe layer 6 and the silicon film 7 are about 40 nm each, a total of which is about 80 nm.

As shown in FIG. 5, a resist film is provided such that the one ends of the silicon film 7 and the SiGe layer 6 are formed so as to extend on the polycrystalline silicon film 5 (or silicon oxide film 4) by lithography. The resist film is employed as a mask for patterning the silicon film 7 and the SiGe layer 6 by dry etching, thereby forming the silicon film 7a and the SiGe layer 6a. At this time, a portion of the polycrystalline silicon film 5, located outside the SiGe layer 6a is removed by etching.

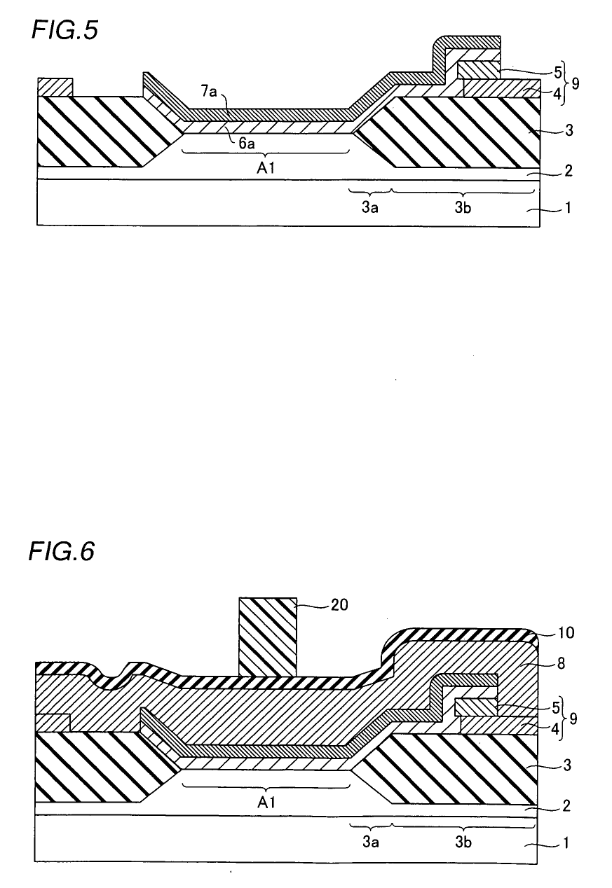

As shown in FIG. 6, a polycrystalline silicon film 8 doped with an n-type impurity having at least about 1×10²⁰ cm⁻³ is formed by low pressure CVD, and a silicon nitride film 10 is formed on this polycrystalline silicon film 8. The thickness of the polycrystalline silicon film 8 is about 200 nm and the thickness of the silicon nitride film 10 is about 50 nm. A resist film 20 having a prescribed patter for fabricating a desired emitter electrode is formed by lithography.

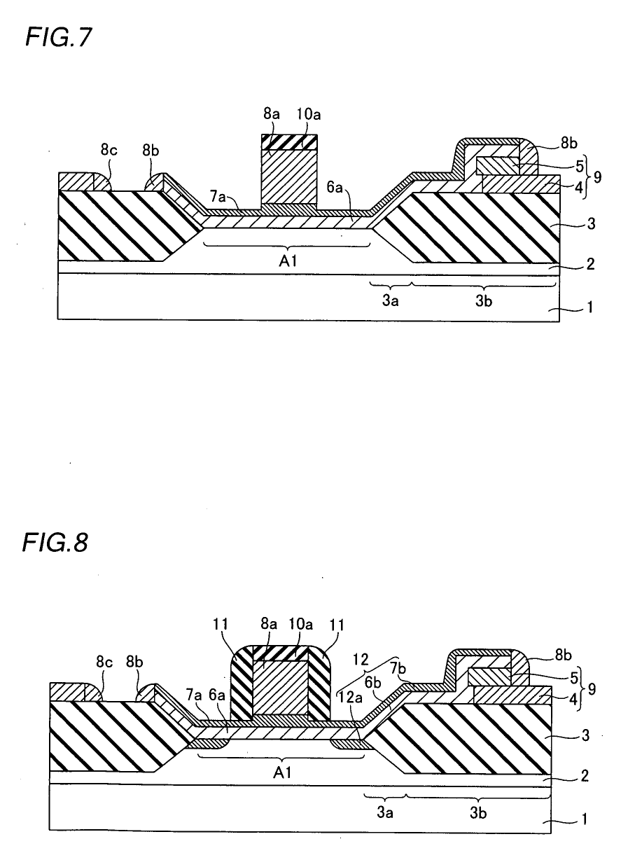

As shown in FIG. 7, the resist film 20 is employed as a mask for patterning the silicon nitride film 10, the polycrystalline silicon film 8 and the silicon film 7 in this order by dry etching. At this time, the patterned silicon nitride film 10 becomes a silicon nitride film 10a. This silicon nitride film 10a serves as a mask employed for etching the polycrystalline silicon film 8. The dry etching is completed in a state where a part of the silicon film 7 remains on an overall surface of the SiGe layer 6a before completely removing the silicon film 7. Consequently, the silicon film 7 becomes a silicon film 7a having a projecting shape in cross section. Then the polycrystalline silicon film 8 is patterned as the emitter electrode 8a serving as the emitter electrode. The polycrystalline silicon film 8 is processed into the side wall 8b formed in the form of a spacer around the SiGe layer 6a and the silicon film 7a and the side wall 8c formed in the form of a spacer around the silicon oxide film 4. Prescribed portions of the element isolation film 3 and the silicon oxide film 4 are exposed.

As shown in FIG. 8, the silicon oxide film employed as an insulating film is deposited on the overall surface by CVD, and a whole-surface etch back is performed by dry etching. Thus, the side wall insulating film 11 made of a silicon oxide film is formed around the silicon nitride film 10a, the emitter electrode 8a and a projecting portion of the silicon film 7a. In this case, the thickness of the silicon oxide film for forming the side wall insulating film 11 is about 200 nm, and the film is formed with a gas mixture of tetraethoxysilane (TEOS)/oxygen (O₂).

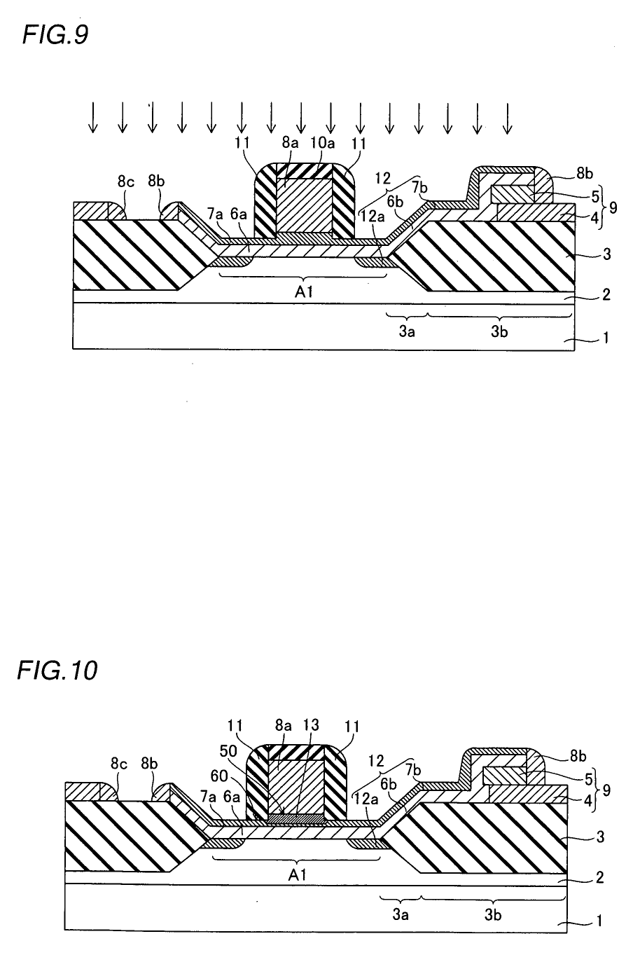

As shown in FIG. 9, the p-type impurity is implanted by ion implantation and activated by thermal treatment. Thus, the outer base layer 12 constituted by the diffusion layer 12a introduced with the p-type impurity and the SiGe layer 6b and the silicon film 7b is formed.

As shown in FIG. 10, the n-type impurity of the emitter electrode 8a is diffused into the silicon film 7a by thermal treatment, thereby forming the emitter layer 13. Consequently, a region containing the n-type impurity (emitter layer 13) and a region containing no n-type impurity are formed on the silicon film 7a, thereby forming an emitter-base junction in the silicon film 7a. The thermal treatment in this process is performed at about 1000° C. for 30 seconds with a RTA device.

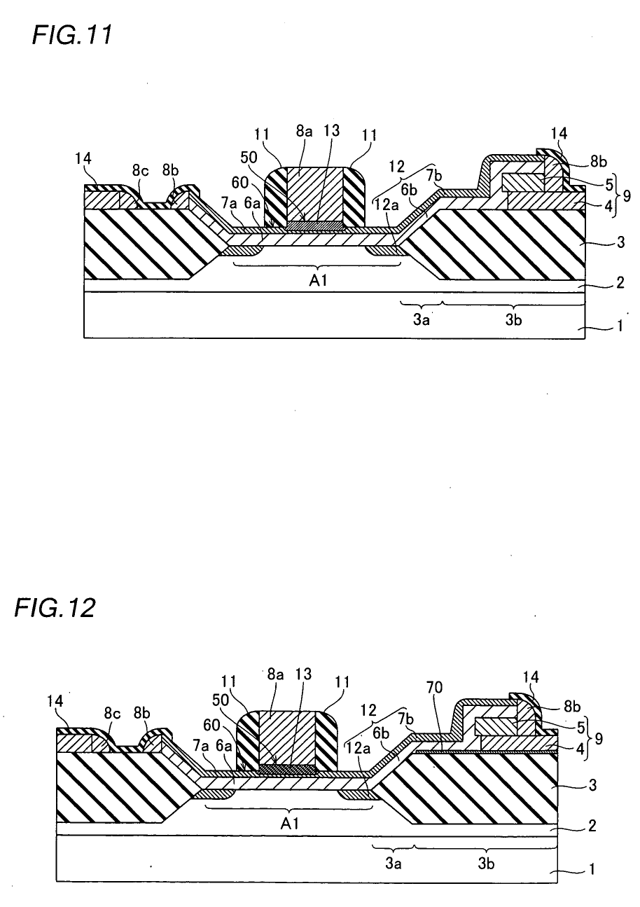

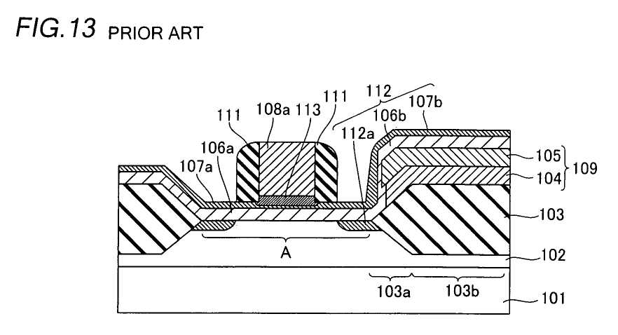

After the thermal treatment, the silicon nitride film 10a on the emitter electrode 8a is removed with, dilute hydrofluoric acid and phosphoric acid. Thereafter the silicon oxide film is deposited on the overall surface by CVD. Then a resist film having a prescribed pattern is formed by lithography and the resist film is employed as a mask for patterning the silicon oxide film by dry etching. Thus, the structure shown in FIG. 11 is obtained. Thus, the patterned silicon oxide film 14 for employing as silicide block for performing silicidation in the next step is formed.

Cobalt (Co) layers are formed on the surfaces of the emitter electrode 8a and the outer base layer 12 and thermal treatment is performed, thereby forming the silicide films (cobalt silicide film) 15a and 15b (thus, an npn bipolar transistor according to this embodiment shown in FIG. 1 is formed). Thereafter an interlayer insulating film such as a plasma TEOS film is deposited on a surface of the semiconductor substrate, and contact portions for connecting a collector layer, a base layer and an emitter electrode portion are formed, and a barrier metal layer made of titanium and a wiring layer made of aluminum are formed (not shown).

According to this embodiment, as hereinabove described, the method of fabricating the semiconductor device comprises a step of forming the uneven portion occurring on the end of the protective film 9 and the uneven portion caused by the inclined portion 3a of the element isolation film 3 at the separate positions, whereby the size of the unevenness is reduced as compared with a case where the uneven portions are formed at the same position. Thus, coatability of the SiGe film 6 with respect to the protective film 9 is improved by the reduced unevenness and hence peeling of the film formed on the SiGe layer 6b or occurrence of defective shape of the silicide film 15b formed on the surface of the SiGe layer 6b in the subsequent steps can be reduced. Therefore, the yield of fabrication can be inhibited from being reduced due to deterioration of the coatability of the SiGe film 6 as the outer base layer and hence the bipolar transistor (semiconductor device) having high reliability can be stably fabricated. The uneven portion occurring on the end of the protective film 9 and the uneven portion caused by the inclined portion 3a of the element isolation film 3 are formed at the separate positions, whereby it is possible to have a margin for accuracy in forming a mask and hence formation of defectives can be suppressed.

When the end of the silicon oxide film 4 as the lower layer is so formed as to have a concave shape with respect to the end of the polycrystalline silicon film 5 as the upper layer (undercut) at the time of performing etching for forming the protective film 9, the SiGe layer 6 and the silicon film 7 formed on the protective film 9 are also formed along the concave shape of the protective film 9, whereby coatability is likely to be deteriorated. According to this embodiment, however, as hereinabove described, the unevenness occurring on the end of the protective film 9 is reduced by the size of the unevenness caused by the inclined portion 3a of the element isolation film 3, whereby deterioration of the coatability of the SiGe layer 6b and the silicon film 7b can be suppressed.

Although the present invention has been described and illustrated in detail, it is clearly understood that the same is by way of illustration and example only and is not to be taken by way of limitation, the spirit and scope of the present invention being limited only by the terms of the appended claims.

While the present invention is applied to the NPN bipolar transistor in the aforementioned embodiment, the present invention is not restricted to this but also applicable to a PNP bipolar transistor in which conductive types of the respective regions are reversed. While the collector layer 2 is formed by forming the epitaxial layer made of silicon on the semiconductor substrate 1, the present invention is not restricted to this. For example, the collector layer may be formed by ion-implanting a p-type or n-type impurity from a surface of a semiconductor substrate 1 reversed in polarity from the impurity.

While the silicide film is formed by employing cobalt in the aforementioned embodiment, the present invention is not restricted to this but the silicide film may be formed by a metal other than cobalt such as titanium (Ti), for example.

In a structure of the aforementioned embodiment, an underlayer film 70 having a thickness thinner than the protective film 9 may be formed on the region covered with no protective film 9 on the element isolation film 3 as in a modification shown in FIG. 12. The SiGe layer 6b having excellent crystallinity can be formed by providing the underlayer film 70 as compared with a case of epitaxially growing the same directly on the element isolation film 3, and hence interconnection resistance of the bipolar transistor can be reduced.

What is claimed is:

1. A semiconductor device comprising:
an element isolation film having an inclined portion and a flat portion;
a protective film formed not on said inclined portion but on said flat portion of said element isolation film; and
an outer base layer formed to extend from on a surface of an active region surrounded by said element isolation film to on said protective film.

2. The semiconductor device according to claim 1, wherein
an end closer to said active region of said protective film is located at a position spaced from a boundary between said inclined portion and said flat portion of said element isolation film toward a side opposite to said active region by a prescribed interval.

3. The semiconductor device according to claim 1, wherein
said protective film includes a silicon oxide film and a polycrystalline silicon film formed on said silicon oxide film, and
an end of said silicon oxide film and an end of said polycrystalline silicon film are located on said flat portion of said element isolation film.

4. The semiconductor device according to claim 3, wherein
said end of said polycrystalline silicon film of said protective film is located on a side closer to said active region than said end of said silicon oxide film.

5. The semiconductor device according to claim 1, wherein
said outer base layer is formed on a region where said protective film of said flat portion is not formed, a surface of said inclined portion and a surface of said protective film.

6. The semiconductor device according to claim 1, further comprising an underlayer film formed on surfaces of said flat portion and said inclined portion and a surface of said protective film, wherein
said outer base layer is formed on a surface of said underlayer film.

7. The semiconductor device according to claim 1, wherein
said outer base layer includes at least a SiGe layer.

8. The semiconductor device according to claim 7, wherein
said outer base layer includes said SiGe layer and a silicon film formed on said SiGe layer, and
a silicide film is formed on said silicon film of said outer base layer.

9. The semiconductor device according to claim 7, wherein
said protective film includes a silicon oxide film and a polycrystalline silicon film formed on said silicon oxide film, and said polycrystalline silicon film of said protective film and said SiGe layer of said outer base layer are in contact with each other.

10. A method of fabricating a semiconductor device, comprising steps of:
forming an element isolation film having an inclined portion and a flat portion on a semiconductor substrate;
forming a protective film so as to be formed not on said inclined portion but on said flat portion of said element isolation film; and
forming an outer base layer so as to extend from on a surface of an active region surrounded by said element isolation film to on said protective film.

11. The method of fabricating a semiconductor device according to claim 10, wherein
said step of forming said protective film includes a step of forming said protective film such that an end closer to said active region of said protective film is arranged at a position spaced from a boundary between said inclined portion and said flat portion of said element isolation film toward a side opposite to said active region by a prescribed interval.

12. The method of fabricating a semiconductor device according to claim 10, wherein
said step of forming said outer base layer includes a step of forming said outer base layer on a region where said protective film of said flat portion is not formed, a surface of said inclined portion and a surface of said protective film.

13. The method of fabricating a semiconductor device according to claim 10, further comprising a step of forming an underlayer film on surfaces of said flat portion and said inclined portion and a surface of said protective film, wherein
said step of forming said outer base layer includes a step of forming said outer base layer on a surface of said underlayer film.

14. The method of fabricating a semiconductor device according to claim 10, wherein
said outer base layer includes at least a SiGe layer.

15. The method of fabricating a semiconductor device according to claim 14, wherein
said outer base layer includes said SiGe layer and a silicon film formed on said SiGe layer,
further comprising a step of forming a silicide film on said silicon film of said outer base layer.

16. The method of fabricating a semiconductor device according to claim 14, wherein
said protective film includes a silicon oxide film and a polycrystalline silicon film formed on said silicon oxide film, and
said step of forming said protective film includes a step of forming said protective film such that said polycrystalline silicon film of said protective film is in contact with said SiGe layer of said outer base layer.

17. The method of fabricating a semiconductor device according to claim 16, wherein
said step of forming said protective film includes a step of patterning said polycrystalline silicon film by dry etching such that an end of said polycrystalline silicon film is located on said flat portion, and thereafter patterning said silicon oxide film by wet etching by employing patterned said polycrystalline silicon film as a mask such that an end of said silicon oxide film is located on said flat portion.
